(19) United States
(12) Patent Application Publication
(10) Pub. No.: US 2024/0128079 A1
(43) Pub. Date: Apr. 18, 2024

(54) A METHOD FOR THE MANUFACTURE OF AN IMPROVED GRAPHENE SUBSTRATE AND APPLICATIONS THEREFOR

(71) Applicant: Paragraf Limited, Somersham (GB)

(72) Inventors: Ivor GUINEY, Somersham (GB); Sebastian DIXON, Somersham (GB); Jaspreet KAINTH, Somersham (GB); Thomas James BADCOCK, Somersham (GB); Ross Matthew GRIFFIN, Somersham (GB)

(73) Assignee: Paragraf Limited, Somersham (GB)

(21) Appl. No.: 18/277,360

(22) PCT Filed: Feb. 15, 2022
(86) PCT No.: PCT/EP2022/053690

§ 371 Date: Aug. 15, 2023

(30) Foreign Application Priority Data
Feb. 17, 2021 (GB) 2102218.1

(51) Int. Cl. H01L 21/02; H01L 29/16

(52) U.S. Cl. CPC H01L 21/02527; H01L 21/02381; H01L 21/02488; H01L 29/1606

(57) ABSTRACT

A method for the manufacture of an improved graphene substrate and applications therefor There is provided a method (100) for the manufacture of an electronic device precursor, the method comprising: (i) providing a silicon wafer (200) having a growth surface (205); (ii) forming (105) an insulative layer (210) on the growth surface (205) having a thickness of from 1 nm to 10 nm, preferably 2 nm to 1 nm; (iii) forming (110) a graphene monolayer or multi-layer structure (215) on the insulative layer (210); (iv) optionally forming (115, 120) one or more further layers (220) and/or electrical contacts (225, 230) on the graphene monolayer or multi-layer structure (215); (v) forming (125) a polymer coating (235) over the graphene monolayer or multi-layer structure (215) and any further layers (115) and/or electrical contacts (225, 230); (vi) thinning (130) the silicon wafer (200), or removing the silicon wafer (200) to provide an exposed surface of the insulative layer (210), by etching with an etchant, wherein the silicon wafer (200) is optionally subjected to a grinding step before etching; and (vii) optionally dissolving away (135) the polymer coating (235); wherein the insulative layer (210) and the polymer coating (235) are resistant to etching by the etchant. The resulting conductive graphene substrate can be used in (organic) LEDs, capacitor devices, tunnel FETs and Hall sensors.

The present invention provides a method for the manufacture of an electronic device precursor. In particular, a method which comprises forming graphene on an insulative layer which is itself formed on a silicon wafer. The method further comprises thinning or removing the silicon thereby providing a thin graphene-based electronic device precursor. The present invention also provides an electronic device precursor obtainable by such a method as well as a conductive substrate. The present invention also provides devices including a light emitting or light sensitive device, a capacitor, a tunnel transistor, a biosensor and a Hall-sensor device, along with an electronic circuit comprising such devices.

Two-dimensional (2D) materials, in particular graphene, are currently the focus of intense research and development worldwide. 2D-materials have been shown to have extraordinary properties, both in theory and in practice which has led to a deluge of products incorporating such materials which include coatings, batteries and sensors to name but a few. Graphene is most prominent and is being investigated for a range of potential applications. Most notable is the use of graphene in electronic devices and their constituent components and includes transistors, diodes, LEDs, photovoltaic cells, Hall-effect sensors, current sensors, biosensors and the like.

Accordingly, there are a wide range of electronic devices known in the prior art which have integrated graphene layer structures (single layer or multi-layer graphene) and/or other 2D-materials as key materials for delivering improvements in such devices over earlier devices and electronic products. These include structural improvements through the use of thinner and lighter materials (which can give rise to flexible electronics) as well as performance improvements such as increased electrical and thermal conductance leading to greater operating efficiencies and in some circumstances are transparent or substantially transparent.

WO 2017/029470, the content of which is incorporated herein by reference, discloses methods for producing two-dimensional materials. The method of WO 2017/029470 provides two-dimensional materials, particularly graphene, with a number of advantageous characteristics including: very good crystal quality; large material grain size; minimal material defects; large sheet size; and self-supporting. The method of WO 2017/029470 may be performed using vapour phase epitaxy (VPE) systems and metal-organic chemical vapour deposition (MOCVD) reactors.

During the development of thinner and lighter electronic devices, the present inventors have found that it is problematic to form graphene on increasingly thinner substrates. This is particularly true when using the methods disclosed in WO 2017/029470 due to bowing in thinner substrates/wafers under the conditions required to form graphene. Furthermore, exceptionally thin substrates (of nanometre thickness, such as from 1 nm to 1 μm) are not sufficiently robust, especially substrates of greater than 2 inch (5 cm), and greater than 6 inch (15 cm) diameters. This precludes the scale-up for the manufacture of multiple electronic device precursors and devices necessary for commercial production.

Whilst techniques are known in the art to reduce the thickness of substrates during semiconductor device fabrication, the inventors have found that such techniques could not reliably be used to reduce the thickness of a substrate having a 2D material such a graphene thereon without resulting in damage or contamination of the material. Despite the enormous potential for graphene based devices, graphene is particularly sensitive to contamination such a doping by atmospheric contaminants or chemicals used in the etching/thinning process (also known as “wafer backgrinding”, “wafer thinning” or a “backfinish”). Furthermore, due to the aforementioned issues with robustness of the thinned wafer, thinning to wafer thicknesses of less than 50 μm can be challenging.

US 2014/017883 A1 discloses a system and method for manufacturing a carbon layer. In one embodiment, the method comprises depositing a first metal layer on a substrate, the substrate comprising carbon, epitaxially growing a silicide which comprises forming a layer of carbon over the silicide.

There remains a need in the art for precursors for electronic devices which provide a thin graphene based support for a final electronic device in which it is to be incorporated. So too there remains a need for such electronic devices which incorporate the thin graphene support.

It is an object of the present invention to provide a method for the manufacture of an electronic device precursor, along with electronic device precursors obtainable by such method which overcome, or substantially reduce, the various problems associated with the prior art or at least provide a commercially useful alternative.

Thus, according to a first aspect of the present invention, there is provided a method for the manufacture of an electronic device precursor, the method comprising:
(i) providing a silicon wafer having a growth surface;
(ii) forming an insulative layer on the growth surface having a thickness of from 1 nm to 10 μm, preferably 2 nm to 1 μm;
(iii) forming a graphene monolayer or multi-layer structure on the insulative layer;
(iv) optionally forming one or more further layers and/or electrical contacts on the graphene monolayer or multi-layer structure;
(v) forming a polymer coating over the graphene monolayer or multi-layer structure and any further layers and/or electrical contacts;
(vi) thinning the silicon wafer, or removing the silicon wafer to provide an exposed surface of the insulative layer, by etching with an etchant, wherein the silicon wafer is optionally subjected to a grinding step before etching; and
(vii) optionally dissolving away the polymer coating;
wherein the insulative layer and the polymer coating are resistant to etching by the etchant.

The present disclosure will now be described further. In the following passages, different aspects/embodiments of the disclosure are defined in more detail. Each aspect/embodiment so defined may be combined with any other aspect/embodiment or aspects/embodiments unless clearly indicated to the contrary. In particular, any feature indicated as being preferred or advantageous may be combined with any other feature or features indicated as being preferred or advantageous.

As described above, the present invention provides a method for the manufacture of an electronic device precursor. An electronic device precursor is intended to refer to a component which is capable of being used to manufacture an electronic device such as by the formation or removal of further layers. An electronic device is one which may then be installed into an electrical or electronic circuit, typically by wire bonding to further circuitry or by other methods known in the art such as soldering using “flip chip” style solder bumps. Thus an electronic device is a functioning device when installed in an electronic circuit and current is provided to the device. A precursor requires a further processing step before it can be used as a device.

The method comprises a first step of providing a silicon wafer having a growth surface. The term wafer and substrate may be used interchangeably and are well understood by those skilled in the art of semiconductor device fabrication. The growth surface is typically a substantially flat surface of wafer. The present invention utilities a silicon wafer to manufacture the electronic device precursor. The inventors have found that advantageously, conventional thinning techniques, which are well known for the common silicon wafer, may be used with the additional steps described herein in order to provide a thin electronic device precursor and subsequent devices without contamination or damage of the graphene. By thinning and/or removing the silicon wafer, the inventors have found that this provides an important advantage in that it reduces the amount of thermally insulative material in the device that will trap heat during use. This is particularly advantageous for applications wherein the device is for use in heated environments (or are located near to other components which generate heat), such as above 50° C. By way of example, the device is therefore suitable for use in close proximity to other electronic circuitry or as a component in an engine. In improving the thermal mass of the device, the electronic properties of the graphene layer structure are less susceptible to deviations improving device quality and lifetime and reducing the need for recalibrations.

Preferably, the silicon wafer has a pre-etching thickness of at least 200 microns (i.e. before the insulative layer is formed) and more preferably, from 300 microns to 2 mm. The inventors have found that the quality and uniformity of the graphene formed directly onto thin substrates/wafers can be compromised by wafer bowing during formation. This is particularly pronounced below 200 microns. However, the thicker the silicon wafer the more material there is that needs to be removed. The method described herein allows for the growth of a desired insulative layer of a desired thickness using a sacrificial silicon wafer. A preferred wafer is one having a thickness of from 500 microns to 1.2 mm, since these are readily available at low cost and do not cause undue graphene growth issues due to wafer bow.

The inventors have found that by encapsulating the graphene between a thin insulating layer and a polymer coating, the silicon may be thinned or completely removed thereby leaving a thin electronic device precursor for use in device fabrication. The inventors have found that a thin insulative layer of a desired thickness (desired for the intended electronic device) may be formed on the growth surface of the essentially sacrificial silicon wafer. The method therefore comprises a step of forming an insulative layer on the growth surface, the insulative layer having a thickness of from 1 nm to 10 μm. Preferably the thickness of the insulative layer is from 2 nm to 1 μm and even more preferably from 2 nm to 500 nm. In some embodiments, such as for very high speed applications, a thickness of from 5 nm to 1 μm, preferably, 5 nm to 500 nm may be preferable.

Preferably, the insulative layer is sufficiently thin so as to be transparent. This is particularly preferred in embodiments described herein wherein the precursor is for a light-emitting or light-sensitive device. Transparent as used herein means a transmissivity of greater than 90% at frequencies of light across the range of 400 nm to 700 nm, preferably greater than 90% across the range of 300 nm to 800 nm.

It is preferred that the insulative layer comprises silicon nitride (Si₃N₄), silicon dioxide (SiO₂), aluminium oxide (Al₂O₃), aluminium gallium oxide (AGO) hafnium dioxide (HfO₂), zirconium dioxide (ZrO₂), yttria-stabilised hafnia (YSH), yttria-stabilised zirconia (YSZ), magnesium aluminate (MgAl₂O₄), yttrium orthoaluminate (YAlO₃), strontium titanate (SrTiO₃), zinc oxide (ZnO), cerium oxide (Ce₂O₃), scandium oxide (Sc₂O₃), erbium oxide (Er₂O₃), magnesium difluoride (MgF₂), calcium difluoride (CaF₂), strontium difluoride (SrF₂), barium difluoride (BaF₂), scandium trifluoride (ScF₃), hexagonal boron nitride (h-BN), cubic boron nitride (c-BN) and/or a III/V semiconductor such as aluminium nitride (AlN) and gallium nitride (GaN). Preferably, the insulative layer comprises a material selected from the group consisting of Al₂O₃, AlN, h-BN, c-BN, ZnO, HfO₂, SiO₂ and SiNₓ. As described herein, such materials are particularly preferred since they are typically resistant to an etchant for etching the silicon wafer thereby allowing the silicon wafer to be thinned or completely removed. Al₂O₃, h-BN and HfO₂ are most preferred due to the balance of cost, etch resistance and ease of use.

The insulative layer may be formed by atomic layer deposition, physical vapour deposition, such as electron beam deposition or thermal evaporation, chemical vapour deposition, plasma enhanced chemical vapour deposition or metal organic chemical vapour deposition. By way of example, the insulative layer is formed by atomic layer deposition (ALD). ALD is technique known in the art and comprises the reaction of at least two precursors in a sequential, self-limiting manner. Repeated cycles of the separate precursors allow the growth of a thin film/layer in a conformal manner (i.e. uniform thickness across the entire substrate) and to a controllable thickness due to the layer-by-layer growth mechanism.

Preferably, the insulative layer is formed by a water-free process. The inventors have found that, especially for Al₂O₃, the growth method can impact the quality of the graphene formed thereon. If ALD, for example, is performed using water (H₂O) and trimethylaluminium (TMAI) to form Al₂O₃, there will always be some trapped water in the ALD layer which can lead to pockets of gas expanding when heated up in the MOCVD reactor for graphene growth. However, the inventors have found that if ALD is performed with oxygen (O₂), or ozone (O₃), and TMAI to form Al₂O₃, then such as issue does not arise. Similarly, ALD is preferably an ammonia (NH₃) free process.

The subsequent step of forming a graphene monolayer or multi-layer structure on the insulative layer may be achieved by any method as is customary in the art, such as by the method disclosed in WO 2017/029470 (which may simply be referred to as by VPE, CVD or MOCVD). By forming, it is intended to mean that graphene is synthesised and produced during the step directly onto the insulating layer. The same applies equally to the other layer described herein which are formed during the method.

Accordingly, the graphene is preferably formed by MOCVD or CVD, and/or the step of forming graphene comprises:
providing the silicon wafer having the insulative layer thereon on a heated susceptor in a reaction chamber, the chamber having a plurality of cooled inlets arranged so that, in use, the inlets are distributed across the wafer and have constant separation from the substrate;
supplying a flow comprising a carbon-containing precursor compound through the inlets and into the reaction chamber to thereby decompose the precursor compound and form the graphene on the insulative layer,
wherein the inlets are cooled to less than 100° C. and the susceptor is heated to a temperature of at least 50° C. in excess of a decomposition temperature of the precursor.

The term “graphene” as used herein refers to a graphene monolayer or multi-layer structure. A graphene monolayer is a single sheet of graphene and in many embodiments is particularly preferable. Single layer or monolayer graphene offers unique electronic properties as it is a zero band gap semiconductor (i.e. a semi-metal) wherein the density of states at the Fermi level is zero and lies and the point where the top of the valence band meets the bottom of the conduction band (forming a Dirac cone). Due to the low density of states near the Dirac point, a shift in the Fermi level is particularly sensitive to charge transfer into such pristine graphene. The electronic structure also gives rise to, for example, the quantum Hall-effect. A multi-layer graphene structure comprises 2 or more sheets or layers of graphene and may nevertheless be preferable since multi-layer graphene offers greater thermal and electrical conductivity as well as a band gap which in some embodiments can be desirable. Multi-layer graphene typically consists of 2 to 10 layers of graphene sheets, preferably 2 to 5 layers and most preferably 2 or 3 layers of graphene.

The method further comprises forming a polymer coating over the graphene monolayer or multi-layer structure along with any further layers and/or electrical contacts. The inventors have found that a polymer coating may be formed over the entirety of the exposed graphene to protect the graphene during the step of etching the silicon wafer. The polymer coating also provides mechanical strength and rigidity to the electronic device precursor during removal of the silicon wafer. Therefore, after thinning of the wafer, the method optionally comprises dissolving away the polymer coating. The inventors have found that a polymer coating may be used to protect the graphene in order to allow thinning the silicon wafer. A polymer coating as used herein refer to an organic polymer coating, preferably one comprising polyethylene, polytetrafluoroethylene or polypropylene, preferably HDPE. Preferably the polymer coating consists of the polymer and any optional dopants as described herein (e.g. consists of HDPE and any optional dopant). The final electronic device precursor may then be used for device fabrication, optionally wherein the polymer coating is dissolved to re-expose the graphene surface for the deposition of further layers.

Preferably the polymer coating has a thickness of from 100 microns to 2 mm, more preferably from 200 microns to 1 mm. Since the method of thinning wafers can be problematic due to the thinness of the resulting wafer, providing a thicker polymer layer can provide for more easy handling of the coated structure.

HDPE is particularly preferred since it is highly etch resistant as well as being very cheap and readily available. HDPE can also readily be dissolved to leave the underlying graphene and/or further layers exposed.

In one embodiment, the polymer coating is formed directly on the graphene monolayer or multi-layer structure and the polymer coating comprises a polymer and a dopant. In this embodiment, the polymer has a first doping effect on graphene and the dopant has an opposite and substantially equal second doping effect on graphene. The inventors have found that a polymer coating may unavoidably dope the graphene upon formation. In order to maintain a specific doping level of graphene, in particular when charge neutrality is desired with a charge carrier concentration of less than 5×10¹¹ cm⁻², preferably less than 2×10¹¹ cm⁻², a dopant may be included to counter the doping effect of the polymer material. For example, when graphene is directly contacted with HDPE, the graphene is n-doped and a counter p-type dopant such as F₄TCNQ can be used to protect and maintain the graphene's original charge carrier concentration.

Despite the potential for doping of the graphene, the inventors have nevertheless found that doping by the polymer coating is substantially less than the doping levels achieved in graphene grown on metal substrates. For example, it is well known that highly uniform graphene may be grown on a catalytic metal substrate, e.g. copper foil, but that the copper substrate results in undesirably high levels of copper contamination. Furthermore, whilst it is known to etch the copper substrate away from the graphene, the chemical etchants further contaminate the graphene which ultimately restricts the use of the graphene in electronic devices. Thus, the method described herein differs from known transfer techniques as do the products which can be obtained by such methods.

Optionally, before the formation of a polymer coating and after the formation of graphene, the method comprises forming one or more further layers and/or electrical contacts on the graphene monolayer or multi-layer structure. Such a step is typically employed when manufacturing specific electronic device precursors as described herein, such as those for LED, Hall-sensor and biosensor applications as well as photonic applications such as in the manufacture of modulators and photodetectors. The electrical contacts provide an ohmic contact for connection to an electrical circuit. Preferably, the contacts are metal contacts as is customary in the art, preferably formed of aluminium, chromium, gold, titanium or combinations thereof. In some embodiments, transparent contacts are preferred, indium tin oxide (ITO) being particularly preferable. In these embodiments the further layers may be sufficient to protect the graphene from doping from the polymer, so no dopant is required.

In a further embodiment of the present invention, the method further comprises a pre-treatment step whereby native oxide is removed from the growth surface of the silicon wafer before the step of forming an insulative layer on the growth surface of the silicon wafer. Preferably, the pre-treatment step comprises contacting the growth surface with a flow of hydrogen gas at a temperature in excess of 900° C. to remove the native oxide. Such a step is typically carried out for at least 1 minute, preferably at least 5 or at least 10 minutes and/or at most 30 minutes. Preferably, the temperature is greater than 1000° C. and/or less than 1150° C., which is generally the temperature at which silicon starts to reflow.

Cleaning the growth surface of the silicon wafer is particularly advantageous since this step removes contaminating particles and removes the native oxide thereby reducing the risk of the insulative layer formed thereon in a subsequent step being formed with defects. Thus a highly conformal insulative layer may be deposited on the silicon growth surface which is particularly advantageous since the inventors have found that the defects in the insulative layer may propagate when heated to graphene growth temperatures in the MOCVD reactor during the step of forming graphene thereon which risks damaging the graphene.

The method further comprises a step of thinning the silicon wafer, or removing the silicon wafer to provide an exposed surface of the insulative layer, by etching with an etchant. This serves to thin the silicon wafer. Preferably, etching results in the complete removal of the silicon wafer to expose the insulative layer which was previously deposited thereon. As will be appreciated, the etchant is a species or chemical suitable for etching elemental silicon and the insulating layer and polymer coating are resistant to etching by the etchant. Thus the inventors have found that by providing graphene on an etch resistant insulative layer and forming an etch resistant polymer coating thereon to encapsulate the graphene, along with any optional further layers and/or contacts, the silicon substrate may be removed without risk of contamination or degradation of the 2D material.

Optionally, the silicon wafer is subjected to a grinding step before etching. The silicon wafer is therefore reduced from a pre-etch thickness to a post-etch thickness. Preferably, thinning comprises the grinding step so as to remove from 70 to 99% of the difference between the pre-etch and post-etch thicknesses, preferably 80 to 90%. The remaining 30 to 1% may then be removed chemically with an etchant. Due to the thickness of typical commercial silicon substrates, grinding provides an energy efficient and simple method for removing a relatively large proportion of the silicon. Grinding is a known process (for example, for the manufacture of “through-silicon vias”) and any steps known in the art may be used to achieve grinding of the silicon wafer. For example, a temporary carrier (such as glass, quartz or silicon) may be bonded to the upper surface to facilitate grinding of the silicon wafer having the insulative layer. The temporary carrier may then be removed.

Preferably, the silicon wafer has a post-etching thickness of less than 100 microns, preferably less than 50 microns, more preferably less than 10 microns. Preferably, the post-etch thickness of the silicon wafer (i.e. after etching and the optional grinding) is from 0% to 30% of the pre-etch thickness, preferably 0% to 10%. Accordingly, the silicon wafer may be completely removed (essentially a thickness of 0 microns). By thinning the wafer to be very thin or completely removed, the inventors have found that the electronic device precursor can be transparent. Preferably, the silicon is thinned to be greater than 90% transparent at frequencies of light across the range of 400 nm to 700 nm, preferably greater than 90% across the range of 300 nm to 800 nm.

In one preferred embodiment of the present invention, the etchant is hydrofluoric acid (HF). HF may be in either gaseous or aqueous form where aqueous HF is preferred for safety and handling during the etching process. HF is preferred since it is commonly available and highly effective at etching silicon. However, HF is also highly effective at etching a wide variety of materials including those common in the art of electronic device manufacture. Suitable materials resistant to HF are equally well-known and appropriate HF resistant polymer may be used as described herein for the polymer coating. HPDE is one particularly preferred material for the polymer coating wherein HF is used as an etchant.

However, any suitable silicon etchant may be used in the method of the present invention. Along with HF, other etchants include nitric acid (HNO₃), potassium hydroxide (KOH), ethylenediamine pyrocatechol (EDP) and tetramethylammonium hydroxide (TMAH) and combinations thereof. As will be appreciated, such etchants may be used in any typical formulation and solvent (e.g. water or an alcohol such as methanol, ethanol or isopropanol). Such a process may be referred to as “wet etching”.

As described herein, the insulative layer and the polymer coating are resistant to etching by the etchant so as to allow the silicon wafer to be thinned, and preferably completed removed, by an etchant whilst protecting the graphene encapsulated therein. Accordingly, it is preferred that the insulative layer and the polymer coating are resistant to etching by the etchant such that under the etching conditions the silicon is etched at least 10 times faster by weight, preferably at least 100 times and more preferably at least 1000 times. Preferably, the insulative layer and/or polymer coating has a rate of etching of less than 10 mg/cm 2/day, preferably less than 5 mg/cm 2/day. Most preferably, the insulative layer and the polymer coating can endure indefinitely under the etching conditions. Suitable etching conditions are well known in the art for removal of silicon material and can be adapted as necessary.

As will be appreciated, various silicon etchants are known in the art which have different chemical properties (e.g. HF and HNO₃ are highly acidic whereas KOH and TMAH are highly alkaline). Accordingly, various polymer coatings may be used depending on the etchant used. As described herein, polyethylene, polytetrafluoroethylene or polypropylene are preferred since they are common and robust etch resistant materials which have a negligible doping effect on the graphene. The insulative layer formed of ceramic materials such as Al₂O₃ as described herein are etch resistant to the acidic and alkaline etchants.

In a preferred embodiment, the method provides a plurality of electronic device precursors, and wherein the method further comprises step (viii) of dicing the silicon wafer. The step of dicing the silicon wafer may be performed before step (vi) of thinning the silicon wafer. Accordingly, in this embodiment, the method involves dicing or cutting the silicon wafer so as to separate the individually constructed components (array) on the silicon wafer simultaneously dicing or cutting through the universal polymer coating formed across the array of components. After dicing, the silicon wafer of the individual electronic device precursors may be thinned as described herein. Dicing may preferably be performed after step (vi). When the method further comprises the optional step (vii) of dissolving the polymer coating, dicing may be performed before or after this step. Accordingly, the array of electronic device precursors may be thinned to remove the silicon wafer in one step across the whole array.

Preferably, the method further comprises etching the graphene by laser or plasma etching, preferably oxygen plasma etching, into a desired shape or configuration before forming any of the further layers, contacts or the polymer coating. One preferred embodiment is a Hall-bar configuration for a Hall-sensor, preferably a cross shape. However, any other shape may be etched as desired for a specific final device, such as a rectangle for a transistor. Accordingly, the graphene formed on the insulative layer may be etched to form a plurality (an array) of graphene portions from which a plurality of electronic device precursors may be constructed.

Preferably, the step of forming an insulative layer is performed in a CVD or MOCVD reaction chamber and thereafter, is it preferred that forming graphene and the optional further layer(s) are also performed in the same reaction chamber thereby reducing the complexity of the manufacturing process.

The electronic device precursor is suitable for a variety of different specific electronic devices as described herein. Accordingly, the electronic device precursor is preferably one of a light sensitive or light emitting device precursor, a biosensor device precursor, a transistor device precursor, a capacitor device precursor and a Hall-sensor device precursor.

In a preferred embodiment wherein the electronic device precursor is a light sensitive or light emitting device precursor, the insulative layer has a thickness of less than 10 nm, and the silicon wafer is removed or thinned to less than 10 nm in the method described herein. The method therefore further comprises forming a light sensitive or light emitting structure on a first portion of the graphene monolayer or multi-layer structure (i.e. forming further layers) and further forming a first contact on the light sensitive or light emitting structure in the same step. Additionally, the method comprises forming a second contact:
(a) on the exposed surface of the insulative layer after thinning or removing the silicon; or
(b) on a second portion of the graphene monolayer or multi-layer structure during the step of forming the light sensitive or light emitting structure and first contact; or
(c) on a second portion of the graphene monolayer or multi-layer structure after having dissolved the polymer coating.

The method is particularly advantageous since this allows for the formation of a device precursor comprising an optically transparent substrate which allows for the efficient transmittance of light, either out of the light emitting device (e.g. an LED) or into the light sensitive device (e.g. a solar cell). Light sensitive and light emitting structures are well known in the art and any may be used in the method to manufacture such a device precursor. For example, an LED structure may comprise layers of n-type and p-type GaN, and may further comprise a plurality of InGaN/GaN multiple quantum wells therebetween. An OLED structure may comprise an electron transport layer upon an emissive layer upon a hole transport layer.

The first contact is provided in direct contact with the light emitting or sensitive structure. The second contact of a device precursor may be provided on the graphene or on the back of the exposed insulative layer. Accordingly, the contact may be formed on the graphene, along with the other layers and first contact, and therefore before the formation of the polymer coating. Alternatively, the second contact may be formed on the insulative layer after having formed the polymer coating and removed the silicon substrate to expose the insulative layer. Finally, the contact may instead be provided after having removed the silicon and dissolved the polymer coating but nevertheless on a second portion on the graphene forming an identical device precursor to one wherein the second contact was formed with the further layers.

Preferably, the second contact is formed on the exposed surface of the insulative layer after removing the silicon wafer, and a third contact is formed on a second portion of the graphene monolayer or multi-layer structure, either during the step of forming the light sensitive or light emitting structure and first contact or after having dissolved the polymer coating. The three contacts may also be referred to as source gate and drain contacts as is known in the art. In this embodiment, the second contact on the back of the insulative layer serves as a gate contact and is preferably directly opposite the further layers. Such an embodiment is particularly advantageous since the very thin insulative layer allows for effective modulation of the current through the graphene and is therefore particularly suited for a light emitting device. The method allows for the manufacture of a light emitting device precursor having a transistor configuration whilst also being optically transmissive. The method allows for the formation of very small monitor pixels.

Preferably, the second contact is transparent or is arranged adjacent a light-emitting or light-receiving region of the exposed surface of the insulative layer. This maximises the light either leaving or entering the device. Suitable arrangements such a bus-bars are well-known in the art and well as a framed arrangement of the contact (i.e. such that the contact is arranged around the perimeter of the light emitting or sensitive structure (on either side of the insulative layer)).

In one preferred embodiment, the electronic device precursor is an OLED and the step of dissolving the polymer coating is not performed. The polymer coating advantageously may be retained in order to protect the sensitive organic components of the OLED which would otherwise also likely be damaged by the solvent required for dissolving the polymer coating.

In another preferred embodiment, the electronic device precursor is a biosensor device precursor. The method for the manufacture of a biosensor device precursor requires that the polymer coating is formed directly on the graphene monolayer or multi-layer structure as described herein. Further the polymer coating comprises a polymer and a dopant, and the polymer has a first doping effect on graphene and the dopant has an opposite and substantially equal second doping effect on graphene. The method requires that no optional further layers are formed but first and second electrical contacts are formed on the graphene monolayer or multi-layer structure. After removing the polymer coating, the method comprises depositing a biologically sensitive material between the first and second electrical contacts on an exposed surface of the graphene monolayer or multi-layer structure. Thus, a biosensor which is advantageously very thin and light may be manufactured. Additionally, the biosensor device precursor may be made substantially transparent which is advantageous for an optical biosensor and, more preferably, may be used as part of a multimodal biosensor.

Optionally, the silicon wafer is removed or thinned to less than 10 nm and a third electrical contact is formed, opposite the biologically sensitive material, on the exposed surface of the insulative layer or on the thinned silicon wafer. As described herein with respect to the light emitting or sensitive device precursor, the third contact on the insulative layer may be used as a gate contact in a transistor arrangement which allows for improved sensitivity of the sensor device in use by application of an appropriate gate voltage.

The biologically sensitive material may be any known in the art for biosensor applications. Preferably, the biologically sensitive material is an organelle, cell receptor, nucleic acid, enzyme, antigen, antibody or analyte, more preferably an enzyme or antibody.

In a further preferred embodiment, the electronic device precursor is a transistor device precursor and the insulative layer has a thickness of less than 10 nm. In this embodiment, the step of forming any further layers and electrical contacts comprises:
(a) forming a dielectric layer on a first portion of the graphene monolayer or multi-layer structure,
(b) forming a first contact on a second portion of the graphene monolayer or multi-layer structure,
(c) forming a second contact on the dielectric layer, and
(d) either:
forming a third contact on the exposed surface of the insulative layer after removing the silicon wafer; or
forming a third contact on an exposed surface of the thinned silicon wafer after thinning.

Accordingly, the dielectric layer and first and second contacts are formed before coating with a polymer, thinning the silicon substrate and dissolving the polymer coating. The first contact in direct contact with the graphene may be considered the source contact of the transistor device precursor.

The dielectric material may comprise any material known in the art to be dielectric. Accordingly, the dielectric material is electrically insulating and typically has a high dielectric constant unlike a simple insulator. The dielectric constant (k) of the dielectric material may be greater than 2, preferably greater than 3 and even more preferably greater than 4 (when measured at 1 kHz at room temperature). In some applications for the transistor, such as high frequency applications, it may be preferable for the dielectric constant of the dielectric material to be lower than that which may be used in other applications, such as low frequency applications. Accordingly, k may be less than 10, preferably less than 6. Dielectric materials may therefore polarise in an electric field.

Preferably, the dielectric material comprises LiF, silicon nitride, a dielectric metal oxide, and/or an organic dielectric polymer. Exemplary dielectric materials for use in the method described herein include one or more of PMMA, PVA, PVB, LiF, CaF₂, Al₂O₃, Ga₂O₃, MgAl₂O₄, MgO, SrTiO₃, BaTiO₃, BaHfO₃, Ta₂O₅, Y₂O₃, WO₃, Y-stabilised ZrO₂ (YSZ), Gd₂O₃, LaAlO₃, LiTaO₃, LiAlO₂, Y₃Al₅O₁₂ (YAG), Gd₃Ga₅O₁₂ (GGG), Sc₂O₃, ThO₂, ZnO, TiO₂, SnO₂, ZrO₂, SrO₂, HfO₂, h-BN, c-BN, SiNₓ, SiO₂, SiC, AlN, AlGaAs, AlGaN, and AlP, preferably Al₂O₃, AlN, h-BN, c-BN, ZnO, HfO₂, CaF₂, SiO₂ and SiNₓ. Accordingly, the dielectric layer may be the same material as the insulative layer.

Preferably, the layer of dielectric material has a thickness of less than 300 nm, such as less than 200 nm, less than 150 nm, preferably less than 100 nm and/or greater than 1 nm, such as greater than 5 nm. Accordingly, the dielectric layer may have a thickness of between 1 nm and 300 nm, preferably between 1 nm and 100 nm.

The dielectric layer may be formed by any appropriate technique known in the art to the skilled person. Deposition of an inorganic dielectric, such as a metal oxide, may be achieved by molecular beam deposition (MBD), atomic layer deposition (ALD), chemical vapour deposition (CVD), and/or physical vapour deposition (PVD). Alternatively, deposition of a dielectric may be achieved using standard photolithography techniques.

The method further comprises forming the third contact. The third contact is formed on the backside and is formed on the exposed insulative layer where the silicon has been completely removed or on the thinned silicon wafer if the silicon has not been completely etched away.

In another preferred embodiment of the method described herein, the electronic device precursor is a capacitor device precursor and the insulative layer has a thickness of less than 10 nm. In this embodiment, the step of forming any further layers and electrical contacts comprises:
(a) forming a dielectric layer on a first portion of the graphene monolayer or multi-layer structure,
(b) forming a first contact on a second portion of the graphene monolayer or multi-layer structure,
(c) forming a second graphene monolayer or multi-layer structure on the dielectric layer,
(d) forming a second contact on the second graphene monolayer or multi-layer structure,
and, wherein the polymer coating is formed directly on the second graphene monolayer or multi-layer structure, the polymer coating comprises a polymer and a dopant, the polymer has a first doping effect on graphene and the dopant has an opposite and substantially equal second doping effect on graphene.

Accordingly, unlike the transistor as described herein, a further graphene monolayer or multi-layer structure is formed on the dielectric layer thereby forming a graphene/dielectric/graphene capacitor structure. A contact is formed on each of the graphene layer structures before forming the polymer coating over the entire device precursor thereby coating at least the exposed upper second graphene layer structure and contacts. In this embodiment, the polymer is counter doped so as to counteract the doping effect of the polymer material applied directly to the graphene.

In yet a further preferred embodiment, the electronic device precursor is a Hall-sensor device precursor and the insulative layer has a thickness of less than 50 nm. In this embodiment, the step of forming any further layers and electrical contacts comprises:
(a) forming a further insulative layer on the graphene monolayer or multi-layer structure,
(b) a further step, either before or after forming the further layers and contacts but before the polymer coating is formed, of shaping the graphene monolayer or multi-layer structure into a Hall-sensor configuration, and
(c) forming a plurality of electrical contacts in direct contact with the graphene monolayer or multilayer structure.

Shaping of the graphene is preferably achieved by etching the graphene, preferably laser or plasma etching as described herein. Preferably, the Hall-sensor configuration is a Hall-cross with four “arms” as is known in the art and four contacts are provided, one in direct contact with the extremity of each of the arms of the cross.

Preferably, the insulative layer of the Hall-sensor device precursor has a thickness of less than 10 nm, and the method further comprises forming one or more wires for carrying a current to be sensed on the exposed surface of the insulative layer thinning or removing the silicon. Such a device precursor may be referred to as a current sensor. The thin insulative layer is therefore particularly advantageous since a wire for carrying a current may be arranged in close proximity to the graphene. When in use, the flow of current through the wires generates a magnetic field which can be detected using the Hall-sensor arrangement of the device. Due to low density of states close to the Dirac point in the graphene, the device has particularly high sensitivity to changes in the magnetic field allowing for precise current sensing.

According to a further aspect of the present invention, there is provided an electronic device precursor obtainable by, preferably obtained by, the method of any of the preceding claims.

In a further aspect of the present invention, there is also provided a conductive substrate for an electronic device provided with a removable protective coating, the substrate consisting of:
an insulative layer having a thickness of from 1 nm to 1 μm, and having first and second opposing planar surfaces;
a graphene monolayer or multi-layer structure on the first planar surface of the substrate;
a dissolvable polymer coating over the graphene monolayer or multi-layer structure; and
optionally, a silicon layer on the second planar surface, the silicon layer having a thickness of less than 100 nm.

Thus the present invention provides a substrate upon which an electronic device may be manufactured, the substrate having a uniform and conductive graphene layer structure enclosed and protected between a thin insulative layer and a polymer coating. The conductive substrate may comprise the silicon wafer upon which the insulative layer and graphene are formed, this can be advantageous for structural integrity, but may equally be provided with the silicon substrate already thinned or completely removed.

In order to incorporate the conductive substrate into an electronic device, the silicon layer may be thinned if required and the polymer coating may then be dissolved by the manufacturer of the electronic device. Thereafter, the desired further layers may be formed on the exposed graphene surface along with the necessary electrical contacts as desired. The conductive substrate therefore offers a building block for electronic devices incorporating high quality graphene layer structures and which are exceptionally thin.

Furthermore, the present invention provides a number of device precursors which are preferably obtainable by the methods disclosed herein. Thus, in a further aspect there is provided a light emitting or light sensitive device comprising a conductive support, wherein the conductive support consists of:
an insulative layer having a thickness of from 1 nm to 1 μm, and having first and second opposing planar surfaces;
a graphene monolayer or multi-layer structure on the first planar surface of the insulative layer;
optionally, a silicon layer on the second planar surface, the silicon layer having a thickness of less than 100 nm; and
wherein the device further comprises:
   a light-emitting or light sensitive layer structure on a first portion of the graphene monolayer or multi-layer structure;
   a first contact on the light-emitting or light-sensitive layer structure; and
   a second contact on a second portion of the graphene monolayer or multi-layer structure.

Preferably, the first contact is a source contact, the second contact is a drain contact, and the device further comprises:

a gate contact on the second planar surface of the insulative layer or, when present, on an exposed planar surface of the silicon layer. Preferably, the light emitting device is an OLED.

In a further aspect there is provided a capacitor comprising a conductive support, wherein the conductive support consists of:
an insulative layer having a thickness of from 1 nm to 1 μm, and having first and second opposing planar surfaces;
a graphene monolayer or multi-layer structure on the first planar surface of the insulative layer;
optionally, a silicon layer on the second planar surface, the silicon layer having a thickness of less than 100 nm; and
wherein the capacitor further comprises:
   a dielectric layer on a first portion of the graphene monolayer or multi-layer structure;
   a first contact on the dielectric layer; and
   a second contact on a second portion of the graphene monolayer or multi-layer structure.

In yet a further aspect there is provided a tunnel transistor comprising a conductive support, wherein the conductive support consists of:
an insulative layer having a thickness of from 1 nm to 1 μm, and having first and second opposing planar surfaces;
a graphene monolayer or multi-layer structure on the first planar surface of the insulative layer,
and, optionally, a silicon layer on the second planar surface, the silicon layer having a thickness of less than 100 nm,
wherein the transistor further comprises:
   a dielectric layer on a first portion of the graphene monolayer or multi-layer structure;
   a first contact on the dielectric layer;
   a second contact on a second portion of the graphene monolayer or multi-layer structure; and
   a third contact on the second planar surface of the insulative layer or, when present, on an exposed planar surface of the silicon layer distal from the insulative layer,
   wherein one of the first and second contacts is a source contact and the other is a drain contact and the third contact is a gate contact.

In yet a further aspect there is provided a Hall-sensor device comprising:
an insulative layer having a thickness of from 1 nm to 1 μm, and having first and second opposing planar surfaces, wherein the first planar surface is for directly contacting a wire in which a current is to be sensed;
a graphene monolayer or multi-layer structure on the second planar surface of the insulative layer, wherein the graphene monolayer or multi-layer structure is configured as a Hall-sensor;
a plurality of contacts on the graphene monolayer or multi-layer structure; and
a further insulative layer on the graphene monolayer or multi-layer structure.

Preferably the Hall-sensor device further comprises one or more wires for carrying a current to be sensed in contact with the first planar surface. Such as device may therefore be referred to as a current sensor device.

In a final aspect of the present invention, there is provided an electronic circuit comprising any of the devices described herein. Accordingly, the electronic circuit preferably comprises the light emitting or light sensitive device, capacitor, tunnel transistor or Hall-sensor device. The electronic circuit therefore comprises at least one wire connected to each contact of the devices.

The present invention will now be described further with reference to the following non-limiting figures in which:

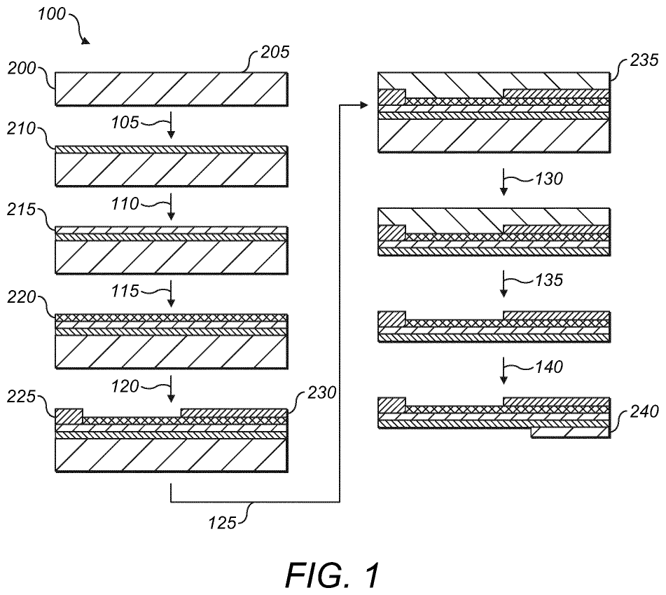

FIG. 1 illustrates a method according to the present invention, specifically a method for manufacturing a tunnel transistor.

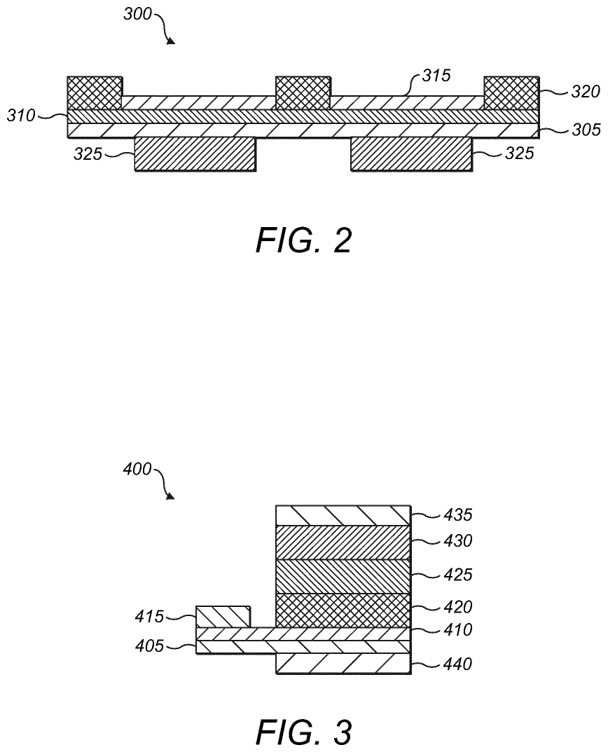

FIG. 2 illustrates a current sensor in accordance with the present invention.

FIG. 3 illustrates a light emitting device in accordance with the present invention.

FIG. 1 exemplifies a method 100 of the manufacture of a graphene-based tunnel transistor. Initially, there is provided a silicon wafer (or substrate) 200, the wafer 200 having a growth surface 205. Typically, the growth surface 205 is an upper surface which is exposed to allow the growth and formation of layers of material. The method 100 comprises a step 105 of forming an insulative Al₂O₃ layer 210 on the growth surface 205 by ALD using trimethyl aluminium and ozone as precursors, the layer of Al₂O₃ layer 210 having a thickness of about 2 nm.

Next, a graphene monolayer 215 is formed on the insulative layer 210 in step 110 using a method as disclosed in WO 2017/029470 in an MOCVD apparatus comprising a close-coupled showerhead. Then in step 115, a further Al₂O₃ layer 220 is formed on the surface of the graphene monolayer 215. Following the formation of the capping Al₂O₃ layer 220, standard photolithography is used to etch the Al₂O₃ layer 220 and expose portions of the graphene monolayer 215. Metal contacts 225, 230 are then deposited in step 120 using conventional e-beam evaporation. For the tunnel transistor, a metal contact 225 is deposited so as to contact the graphene monolayer 215 through the etched Al₂O₃ capping layer 220. The metal contact 225 serves to function as the source contact is the tunnel transistor when functioning in an electronic device. Simultaneously, metal contact 230 is deposited on a distal portion of the Al₂O₃ capping layer 220. The metal contacts 225, 230 are formed from 5 nm titanium followed by 80 nm gold.

An HPDE polymer coating 235 is then formed across the entire wafer 200 in step 125 which protects the other layers from etching in step 130. The silicon wafer 200 is thinned in step 130 by an etchant comprise aqueous HF. The insulative layer 210 prevents any further etching once all of the silicon wafer 200 has dissolved. Accordingly, step 130 exposes a surface of the insulative Al₂O₃ layer 210.

The HDPE coating 235 is then dissolved in step 135 using, for example, toluene as a solvent to liberate the exceptionally thin conductive support. A final metal contact 240 may be deposited in step 140 on the back-side of the support, i.e. on the exposed surface of the insulative Al₂O₃ layer 240. This contact may serve as the drain contact when connected to a circuit and the metal contact 230 as a gate contact.

FIG. 2 is a cross-section of a current sensor 300 according to the present invention. The current sensor 300 may be viewed as an embodiment of a Hall-sensor comprising two wires 325 for carrying a current to be sensed.

The current sensor 300 comprises an insulative layer 305 formed of HfO₂ having a thickness of about 1 nm which provides very sensitive and accurate current sensing due to the close proximity of the current carrying wires 325 to the monolayer of graphene 310 on the opposite planar surface of the insulative layer 305. The current sensor 300 further comprises a further insulative layer 315 which serves to protect the graphene from atmospheric contamination. Additionally, the sensor 300 also comprises a plurality of contacts 320 in contact with the graphene 310 so as to enable device function when installed into an electronic circuit.

FIG. 3 is a cross-section of a light emitting device 400, specifically an OLED comprising a conductive support. The conductive support consists of the SiNₓ insulative layer 405 having first and second opposing planar surfaces and graphene bi-layer 410 on the first planar surface of the insulative layer 405 which permits greater current flow into the emissive material of the OLED.

The OLED 400 further comprises a light-emitting structure (420, 425, 430) on a first portion of the graphene bilayer 410. The light-emitting structure of the OLED 400 is formed of a hole transport layer 420 such as TPD or PEDOT:PSS, which is on the graphene bilayer 410. Upon the HTL is the emissive layer 425 such as Alq₃ or a polyfluorene. Finally, an electron transport layer 430 such as LiF is provided on the emissive layer 425.

The OLED 400 further comprises three metal contacts necessary for connection to an electronic circuit. A contact 415 is provides in contact with the bi-layer graphene 405 as the source contact. The drain contact 435 is provided on the electron transport layer 430 of the light-emissive structure and finally a gate contact is provided on the second planar surface of the insulative layer 405, ideally across an equivalent area of the light-emitting stack to provide for effective modulation of the current through the graphene 405 and into the light-emitting stack. The very thin insulative layer 405 enables very low voltages to be used to modulate the electronic properties of the graphene 410 and therefore the function of the OLED 400 in an electronic circuit.

### EXAMPLES

A 675 micron thick silicon wafer is placed into an ALD chamber and held in the chamber at the deposition temperature of 150° C. under a vacuum of approximately 220 mTorr (about 27 Pa) with a nitrogen gas flow of 20 sccm to equilibrate the chamber temperature and pressure, as well as desorb any moisture from the sample surface. Al₂O₃ is then deposited using trimethyl aluminium (TMAI) and ozone (O₃) as the metalorganic and oxidant precursor, respectively, which are introduced into the deposition chamber using nitrogen as both the carrier and purge gas. The precursors are pulsed into the chamber in a 3:2 ratio, with pulse times of 0.6 seconds and purge times of 20 and 25 seconds for TMAI and O₃, respectively. Films are deposited at 150° C. with varying numbers of cycles (between 10 and 200 cycles) depending on the desired film thickness.

The silicon wafer with the insulating layer thereon is placed within an MOCVD reactor upon a silicon carbide-coated graphite susceptor. The wafer is rotated on the susceptor at a rate of 30-120 rpm. The sealed chamber is purged with a gas mixture which may contain nitrogen, argon, helium and/or hydrogen. The wafer is heated on the susceptor to its anneal conditions, in this example from 850-900° C. under a reduced pressure of from 50-200 mbar. The wafer is annealed for a period of 10-20 min. The wafer is then heated to the growth temperature for the graphene deposition, such as from 1100-1200° C., as measured optically using in-situ pyrometry (corresponding to a heater temperature of about 1200-1400° C.). The growth is typically conducted under reduced pressure with continuing flow of an inert/reducing gas mixture comprising nitrogen, argon, helium and/or hydrogen, at 50-100 mbar. Graphene growth commences by adding a carbon-containing precursor vapour (e.g. n-hexane, methane, bromomethane, 3-hexyne, azoethane, bis-cyclopentadienyl magnesium) to the gas mixture. The heated substrate is exposed to the graphene precursor for a period of 2500-4000 seconds. At the end of the graphene growth step, the graphene-coated substrate is cooled under flow of inert/reducing gas to a safe removal temperature, preferably below 150° C.

An Al₂O₃ layer is grown on the graphene using an equivalent process as that described for growth on the silicon wafer. Longer purge times are required at lower deposition temperatures to ensure all excess precursor and by-products are removed from the chamber. Films are deposited at 40° C. with varying numbers of cycles (between 10 and 200 cycles) depending on the desired film thickness. Atmospheric exposure to the graphene samples is kept to a minimum, with maximum exposure times of approximately 2 minutes. The pre-deposition equilibrium time should be sufficient to remove any adsorbed moisture.

Ohmic contacts are formed on the device by contacting directly to the graphene. In this case, the full structure (graphene with dielectric layer grown on top) is first coated with a standard photoresist (e.g. Shipley S1813). This is achieved by dropping the resist on the top of the wafer, and putting the wafer into a spin coater system at 1500 rpm for 60 seconds until the resist is spread over the entire wafer. It is then baked on a hot plate in the air at 105° C. for 120 seconds. Next, a UV mask exposer is used to open up areas for the Ohmic contacts. A reactive ion etching system which includes chlorine gas is used to etch through the resist in the Ohmic contact exposed areas—this etches through the dielectric Al₂O₃ capping layer on top of the graphene, etches through the graphene and etches at least a few monolayers into the Al₂O₃ insulative layer underneath the graphene. This opens up the side of the graphene, i.e. the side of the hexagon, which is known to result in lower contact resistances than when Ohmic contact metals are deposited on top of the graphene sheet. Next, the etched wafer is loaded into an e-beam evaporation system. The system is pumped down to low pressure, ideally less than 10-6 mbar to minimise as many impurities, including water, as possible in the system. Next, 5 nm of titanium is evaporated onto the wafer, as a wetting layer contacting the graphene directly. 80 nm of gold is then evaporated on top of this. The system is then pumped up to atmospheric pressure and the wafers are taken out. The remaining resist is removed using Microchem LOR 10A.

A 500 micron thick high-density polyethylene polymer coating is then formed over the entirety of the upper surface of the intermediate silicon wafer having an alumina/graphene/alumina stack comprising Ti/Au contacts. The HPDE coated intermediate is then etched by contacting with an aqueous solution of tetramethyl ammonium hydroxide (about 25 wt %). Complete etching of the silicon wafer at room temperature, so as to expose the surface of the alumina layer initially deposited on the silicon wafer, is achieved within one day to yield an electronic device precursor which is then washed with deionised water and dried under a flow of nitrogen gas.

As used herein, the singular form of “a”, “an” and “the” include plural references unless the context clearly dictates otherwise. The use of the term “comprising” is intended to be interpreted as including such features but not excluding other features and is also intended to include the option of the features necessarily being limited to those described. In other words, the term also includes the limitations of “consisting essentially of” (intended to mean that specific further components can be present provided they do not materially affect the essential characteristic of the described feature) and “consisting of” (intended to mean that no other feature may be included such that if the components were expressed as percentages by their proportions, these would add up to 100%, whilst accounting for any unavoidable impurities), unless the context clearly dictates otherwise.

It will be understood that, although the terms “first”, “second”, etc. may be used herein to describe various elements, layers and/or portions, the elements, layers and/or portions should not be limited by these terms. These terms are only used to distinguish one element, layer or portion from another, or a further, element, layer or portion. It will be understood that the term “on” is intended to mean “directly on” such that there are no intervening layers between one material being said to be “on” another material. For example, forming electrical contacts on the graphene therefore refers to electrical contacts in direct contact with the graphene surface and/or an edge thereof. Spatially relative terms, such as “below”, “beneath”, “lower”, “above”, “upper” and the like, may be used herein for ease of description to describe one element or feature's relationship to another element(s) or feature(s). It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented and the spatially relative descriptors used herein interpreted accordingly.

The foregoing detailed description has been provided by way of explanation and illustration, and is not intended to limit the scope of the appended claims. Many variations of the presently preferred embodiments illustrated herein will be apparent to one of ordinary skill in the art, and remain within the scope of the appended claims and their equivalents.

1. A method for the manufacture of an electronic device precursor,
the method comprising:
(i) providing a silicon wafer having a growth surface;
(ii) forming an insulative layer on the growth surface having a thickness of from 1 nm to 10 μ;
(iii) forming a graphene monolayer or multi-layer structure on the insulative layer;
(iv) optionally forming one or more further layers and/or electrical contacts on the graphene monolayer or multi-layer structure;
(v) forming a polymer coating over the graphene monolayer or multi-layer structure and any further layers and/or electrical contacts;
(vi) thinning the silicon wafer, or removing the silicon wafer to provide an exposed surface of the insulative layer, by etching with an etchant, wherein the silicon wafer is optionally subjected to a grinding step before etching; and
(vii) optionally dissolving away the polymer coating;
wherein the insulative layer and the polymer coating are resistant to etching by the etchant.

2. The method according to claim 1, wherein the polymer coating is formed directly on the graphene monolayer or multi-layer structure and wherein the polymer coating comprises a polymer and a dopant, wherein the polymer has a first doping effect on graphene and the dopant has an opposite and substantially equal second doping effect on graphene.

3. The method according to claim 1, wherein the silicon wafer has a pre-etching thickness in step (i) of at least 200 microns and/or wherein the silicon wafer has a post-etching thickness after step (vi) of less than 100 microns.

4. (canceled)

5. The method according to claim 1, wherein the insulative layer comprises a material selected from the group consisting of Al₂O₃, AlN, h-BN, c-BN, ZnO, HfO₂, SiO₂ and SiNₓ.

6. The method according to claim 1, wherein the insulative layer is formed by ALD and/or in a water-free process.

7. (canceled)

8. The method according to claim 1, wherein the insulative layer and the polymer coating are resistant to etching by the etchant such that under the etching conditions the silicon is etched at least 10 times faster by weight.

9. The method according to claim 1, wherein the polymer coating comprises HDPE.

10. The method according to claim 1, wherein the etchant is HF in gaseous or aqueous form.

11. The method according to claim 1, wherein in step (vi) the silicon wafer is reduced from a pre-etch thickness to a post-etch thickness and wherein step (vi) comprises a grinding step to remove from 70 to 99% of the difference between the pre-etch and the post-etch thicknesses.

12. The method according to claim 1, wherein step (ii) is performed in a CVD or MOCVD reaction chamber.

13. The method according to claim 1, wherein the electronic device precursor is a light sensitive or light emitting device precursor, wherein the insulative layer has a thickness of less than 10 nm, wherein the silicon wafer is removed or thinned to less than 10 nm in step (vi), and
wherein the method comprises forming a light sensitive or light emitting structure on a first portion of the graphene monolayer or multi-layer structure in step (iv), and forming a first contact on the light sensitive or light emitting structure in step (iv), and forming a second contact:
(a) on the exposed surface of the insulative layer after step (vi); or
(b) on a second portion of the graphene monolayer or multi-layer structure in step (iv); or
(c) on a second portion of the graphene monolayer or multi-layer structure after step (vii).

14. The method according to claim 13, wherein the second contact is formed on the exposed surface of the insulative layer after removing the silicon wafer in step (vi), and a third contact is formed on a second portion of the graphene monolayer or multi-layer structure, either in step (iv) after step (vii).

15. The method according to claim 13, wherein the second contact is transparent or is arranged adjacent a light-emitting or light-receiving region of the exposed surface of the insulative layer.

16. The method according to claim 13, wherein the electronic device precursor is an OLED and wherein step (vii) is not performed.

17. The method according to claim 2, wherein the electronic device precursor is a biosensor device precursor, wherein no further layers are formed in step (iv), wherein first and second electrical contacts are formed on the graphene monolayer or multi-layer structure in step (iv), wherein the method comprises depositing a biologically sensitive material between the first and second electrical contacts on an exposed surface of the graphene monolayer or multi-layer structure after step (vii),
and, optionally, the silicon wafer is removed or thinned to less than 10 nm in step (vi) and a third electrical contact is formed, opposite the biologically sensitive material, on the exposed surface of the insulative layer or on the thinned silicon wafer.

18. (canceled)

19. The method according to claim 1, wherein the electronic device precursor is a transistor device precursor, wherein the insulative layer has a thickness of less than 10 nm,
wherein the method comprises in step (iv):
(a) forming a dielectric layer on a first portion of the graphene monolayer or multi-layer structure,
(b) forming a first contact on a second portion of the graphene monolayer or multi-layer structure,
(c) forming a second contact on the dielectric layer, and
(d) either:
forming a third contact on the exposed surface of the insulative layer after step (vi); or
forming a third contact on an exposed surface of the thinned silicon wafer after step (vi).

20. The method according to claim 1, wherein the electronic device precursor is a capacitor device precursor, wherein the insulative layer has a thickness of less than 10 nm,
wherein the method comprises in step (iv):
(a) forming a dielectric layer on a first portion of the graphene monolayer or multi-layer structure,
(b) forming a first contact on a second portion of the graphene monolayer or multi-layer structure,
(c) forming a second graphene monolayer or multi-layer structure on the dielectric layer,
(d) forming a second contact on the second graphene monolayer or multi-layer structure,
and, wherein in step (v) the polymer coating is formed directly on the second graphene monolayer or multi-layer structure and wherein the polymer coating comprises a polymer and a dopant, wherein the polymer has a first doping effect on graphene and the dopant has an opposite and substantially equal second doping effect on graphene.

21. The method according to claim 1, wherein the electronic device precursor is a Hall-sensor device precursor, wherein the insulative layer has a thickness of less than 50 nm, wherein the method comprises:
(a) forming a further insulative layer on the graphene monolayer or multi-layer structure in step (iv),
(b) a further step, between steps (iii) and (iv) or between steps (iv) and (v), of shaping the graphene monolayer or multi-layer structure into a Hall-sensor configuration, and
(c) forming a plurality of electrical contacts in direct contact with the graphene monolayer or multilayer structure.

22. The method according to claim 21, wherein the insulative layer has a thickness of less than 10 nm, and wherein the method further comprises:
forming one or more wires for carrying a current to be sensed on the exposed surface of the insulative layer after step (vi).

23. (canceled)

24. A conductive substrate for an electronic device provided with a removable protective coating, the substrate consisting of:
an insulative layer having a thickness of from 1 nm to 1 μm, and having first and second opposing planar surfaces;
a graphene monolayer or multi-layer structure on the first planar surface of the substrate;
a dissolvable polymer coating over the graphene monolayer or multi-layer structure; and
optionally, a silicon layer on the second planar surface, the silicon layer having a thickness of less than 100 nm.

25-32. (canceled)
